(19) United States
(12) Patent Application Publication
(10) Pub. No.: US 2024/0364037 A1
(43) Pub. Date: Oct. 31, 2024

(54) CAMM CONNECTOR PIN WITH MULTI-SPRING (DUAL BEND DIRECTION) LEVERS

(71) Applicant: Intel Corporation, Santa Clara, CA (US)

(72) Inventors: Landon HANKS, Milwaukie, OR (US); Douglas HEYMANN, Portland, OR (US); John R. DREW, Aloha, OR (US); Xiang LI, Portland, OR (US)

(21) Appl. No.: 18/768,742

(22) Filed: Jul. 10, 2024

(51) Int. Cl. H01R 13/24

(52) U.S. Cl. CPC H01R 13/2478

(57) ABSTRACT

Compression Attached Memory Module (CAMM) connector pin with multi-spring (dual bend direction) levers and associated connectors. The connector pin comprises an upper cantilevered spring member coupled to an upper portion of a body and a lower cantilevered spring member coupled to a lower portion of the body. Each of the upper and lower cantilevered spring members include at least one forward bending lever and a backward bending lever. The upper cantilevered spring member may have a pair of arms merging to form an upper unified spring member having a nose and looping backwards over the arms and having an apex. A lower cantilevered spring may have a pair of legs merging to form a lower unified spring member having a nose and looping backwards under the legs and having a bottom. When compressed the forward and backward bending levers counteract one another in the horizontal plane, reducing horizontal displacement.

### BACKGROUND INFORMATION

Memory on Package (MOP) architecture provides high memory speeds and low power for thin and light mobile market segments, such a mobile devices, laptops, notebooks, etc. Under one conventional MOP approach, DRAM (Dynamic Random Access Memory) chips are mounted onto the topside of the package, side by side with a CPU (Central Processing Unit) and/or System on Chip (SoC) die. A drawback of this approach is that the DRAM chips (or module carrying the DRAM chips) are permanently coupled to the package. As a result, the memory cannot be upgraded (e.g., add more memory or replace with faster memory) or cannot be replaced upon failure.

One approach for addressing the foregoing is the Compression Attached Memory Module (CAMM) Connector, which is a new connector technology introduced in 2022. CAMM connectors with current geometry are showing density, mechanical, and signaling challenges when applied to developing platforms.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIGS. 1a, 1b, 1c, and 1d respectively show isometric side, rear, and top views of a current CAMM connector pin;

FIGS. 2a, 2b, 2c, and 2d respectively show isometric side, rear, and top views of a new proposed CAMM connector pin, according to one embodiment;

FIGS. 3a and 3b show further isometric views of the CAMM connector pin of FIGS. 2a, 2b, 2c, and 2d;

FIGS. 4a, 4b, and 4c show side profiles of the existing CAMM connector pin in an uncompressed state, a compressed state, and an overlap of the two;

FIGS. 5a, 5b, and 5c show side profiles of the proposed CAMM connector pin in an uncompressed state, a compressed state, and an overlap of the two;

FIG. 6 shows a side profile comparison between the existing and proposed CAMM connector pin;

FIGS. 7a and 7b show cutaway isometric views of a CAMM connector including a plurality of the proposed CAMM connector pin, according to one embodiment;

FIG. 7c shows a cutaway top view of the CAMM connector of FIGS. 7a and 7b, illustrating a first CAMM connector pin configuration, according to one embodiment;

FIG. 8 shows a second CAMM connector pin configuration under which the pins in alternating rows are flipped vertically, according to one embodiment;

FIG. 9 shows a third CAMM connector pin configuration under which pins are arranged in rows and columns and tilted approximately 30 degrees, according to one embodiment;

FIG. 10 shows a comparison between pin configurations for the current CAMM connector pin and the proposed CAMM connector pin, wherein both configurations have the same number of pins and the same horizontal pitch;

FIG. 11 shows a comparison between the existing CAMM connector pin configuration of FIG. 10 and a CAMM connector pin configuration using the proposed design that further includes extra rows of GND pins, according to one embodiment;

FIG. 12 is a graph illustrating a far end cross talk (FEXT) power sum comparison between the current and proposed (new) pin configurations of FIG. 10 and the new pins with extra row of GND configuration of FIG. 11; and

FIG. 13 is a graph illustrating Time Domain Reflectometry (TDR) impedance vs. time using the current and proposed (new) pin configurations of FIG. 10 and the new pins with extra row of GND configuration of FIG. 11.

### DETAILED DESCRIPTION

Embodiments of a CAMM connector pin with multi-spring (dual bend direction) levers and associated connectors are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

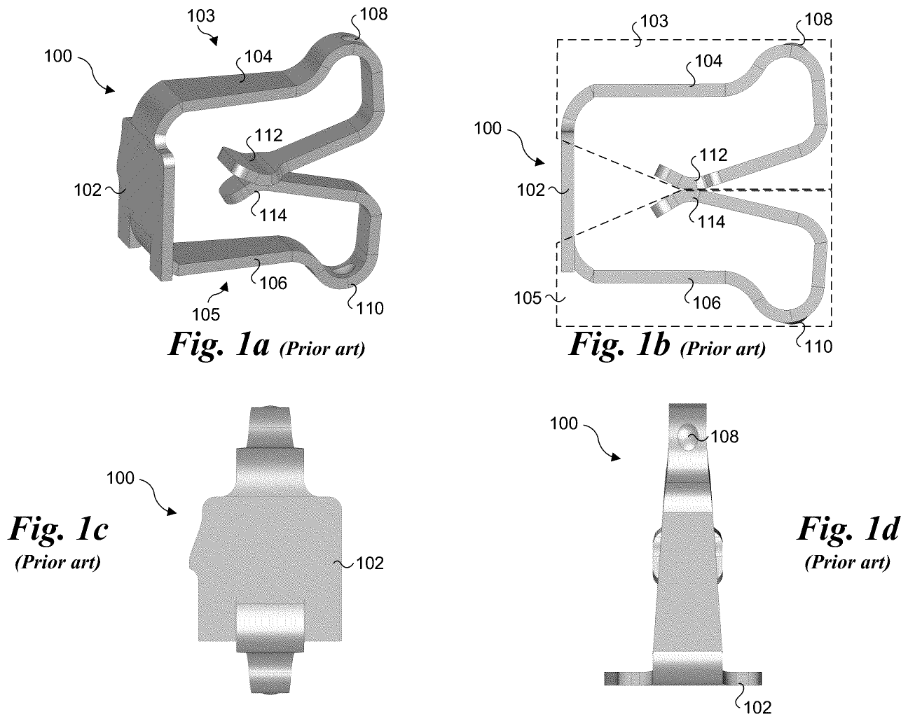

FIGS. 1a, 1b, 1c, and 1d respectively show isometric, side, rear, and top views of a current CAMM connector pin 100 in a compressed state. CAMM connector pin 100 includes a body 102 to which an upper cantilevered spring member 103 including a forward bending lever 104 and a lower cantilevered spring member 105 including a forward bending lever 106 are coupled. Upper cantilevered spring member 103 further includes a contact surface 108 and a shunting lever 112, while lower cantilevered spring member 105 further includes a contact surface 110 and a shunting lever 114.

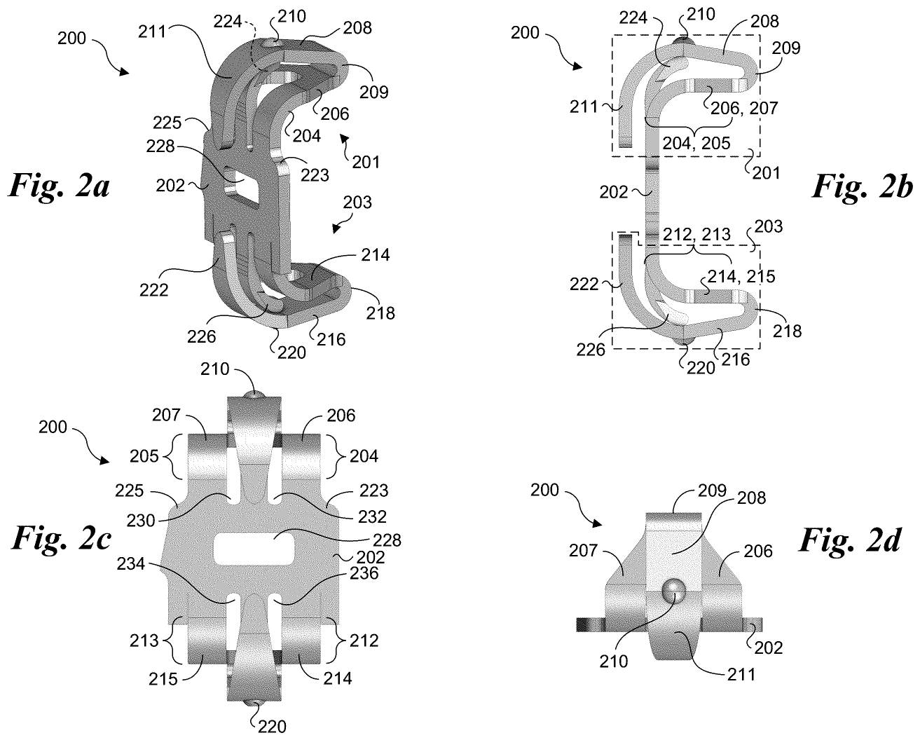

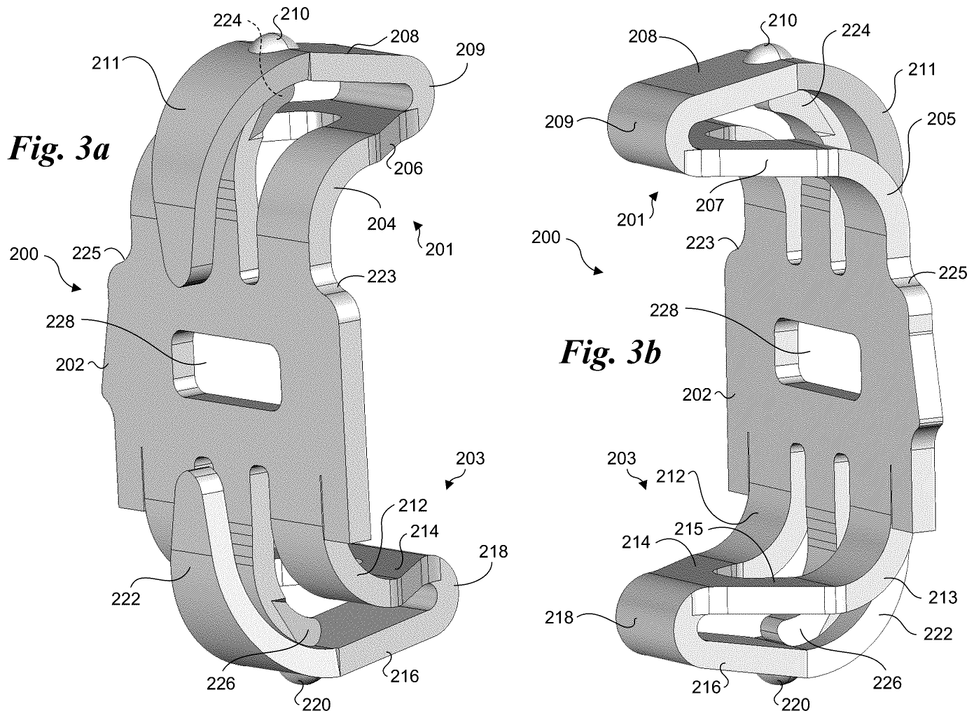

FIGS. 2a, 2b, 2c, and 2d respectively show isometric, side, rear, and top views of a proposed CAMM connector pin 200 in a compressed state, according to one embodiment. FIGS. 3a and 3b also show respective isometric views of CAMM connector pin 200. CAMM connector pin 200 includes an upper cantilevered spring member 201 attached to an upper portion of a body 202 and a lower cantilevered spring member 203 attached to a lower portion of body 202. Upper cantilevered spring member 201 includes a pair of arms 204 and 205 including respective forward bending levers 206 and 207 coupled to a backward bending lever 208 via a nose 209. Upper cantilevered spring member 201 further includes a contact surface 210 and a tail 211. As illustrated, arms 204 and 205 are coupled at respective shoulders 223 and 225 of body 202 and merge into a unified spring member that begins just prior to nose 209, forming a generally y-shaped configuration. The unified spring member loops backwards above arms 204 and 205 until it reaches an apex that is substantially coincident with contact surface 210, and then bends downward to form tail 211.

Lower cantilevered spring member 203 includes a pair of legs 212 and 213 having respective forward bending levers 214 and 215 coupled to a backward bending lever 216 via a nose 218. Lower cantilevered spring member 203 further includes a contact surface 220 and a tail 222. As illustrated, legs 212 and 213 are coupled at respective lower portions of body 202 and merge into a unified spring member that begins just prior to nose 218, forming a generally y-shaped configuration. The unified spring member loops backwards below legs 212 and 213 until it reaches a bottom that is substantially coincident with contact surface 220, and then bends upward to form tail 222.

CAMM connector pin 200 also includes an upper cantilevered shunting lever 224 coupled to an upper portion of body 202 and a lower cantilevered shunting lever 226 coupled to a lower portion of body 202. As shown in FIG. 2b, when CAMM connector pin 200 is compressed the free end of upper cantilevered shunting lever 224 is in contact with the inner surface of upper cantilevered spring member 201 below contact surface 210, while the free end of lower cantilevered shunting lever 226 is in contact with the inner surface of lower cantilevered spring member 203 above contact surface 220. The upper and lower cantilevered shunting levers 224 and 226 create a shunted electric path between contact surfaces 210 and 220 when in this compressed configuration. In one embodiment, contact surfaces 210 and 220 have a hemispherical shape.

As shown in FIGS. 2a and 2c, a hole 228 is formed in body 202. Also, the structure of CAMM connector pin 200 further includes slots 230, 232, 234, and 236, as shown in FIG. 2c.

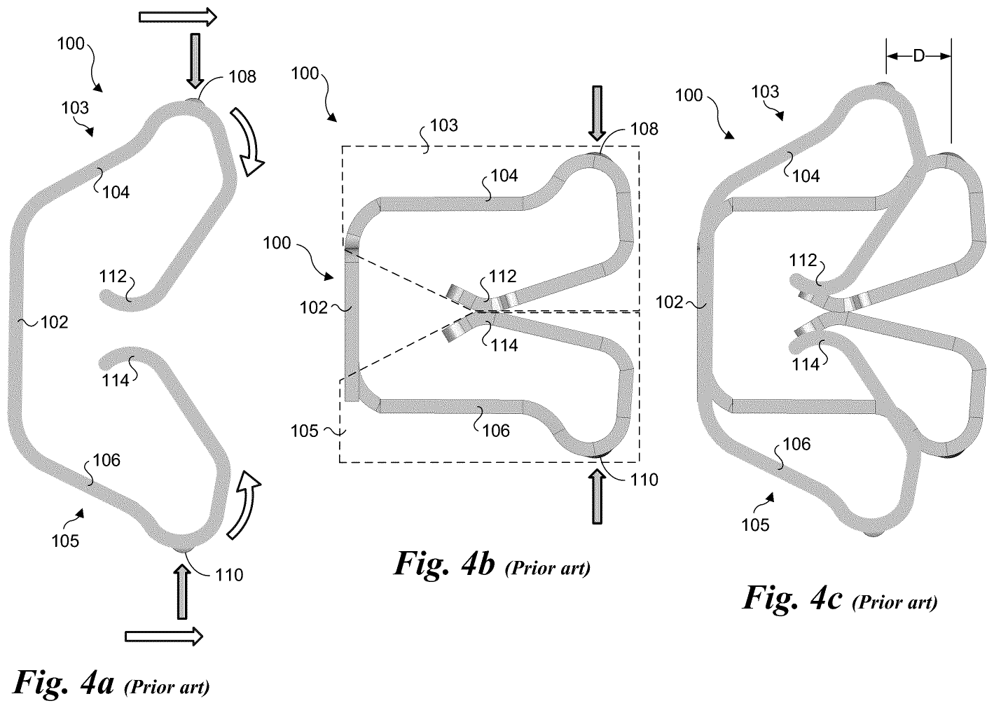

FIGS. 4a and 4b respectively show CAMM connector pin 100 in an uncompressed state and a compressed state. When installed in a CAMM connector housing slot in a CAMM connector disposed between an upper board with a first array of contact pads on its underside and a lower board with a second array of contact pads on its topside, contact surface 108 will be in contact with a contact pad in the first array of contact pads and contact surface 110 will be in contact with a contact pad in the second array of contact pads. The free ends of shunting levers 112 and 114 are contact, creating a shunted electrical path via the contact surface.

When installed in a CAMM connector housing slot, body 102 is fixed to the CAMM connector housing such that it does not move relative to the housing. As shown in FIG. 4a, when CAMM connector 100 is compressed by applying compression at contact surfaces 108 and 110, upper cantilevered spring member 103 is caused to move forward and rotated downward, while lower cantilevered spring member 105 is caused to move forward and rotated upward. FIG. 4b shows the final compressed configuration. This results in a substantial displacement ‘D’ of contact surfaces 108 and 110 in the horizontal plane as shown in FIG. 4c. This substantial displacement requires the contact pads on the boards to be rectangular and elongated, reducing the density of the connector pins used in current CAMM connectors.

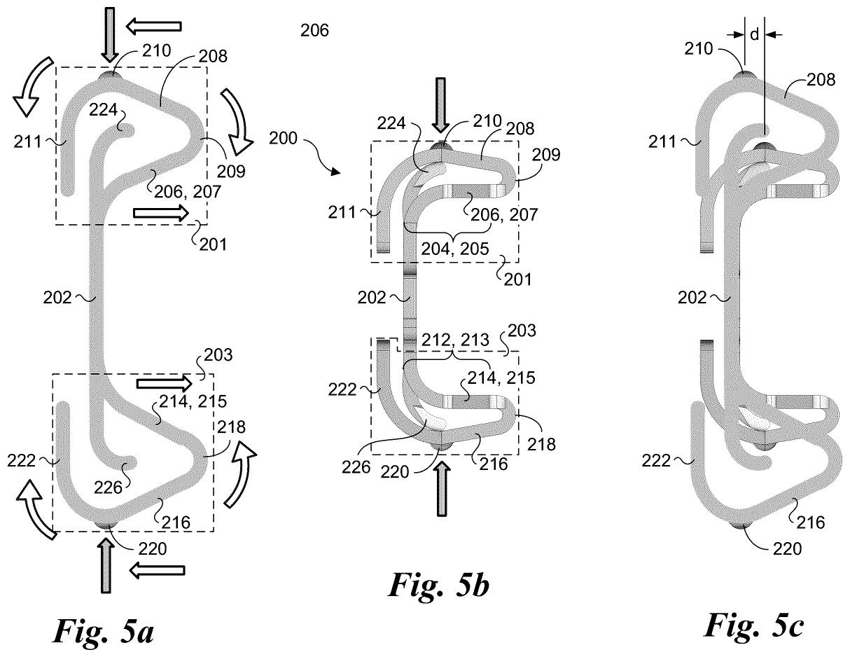

FIGS. 5a and 5b respectively show CAMM connector pin 200 in an uncompressed state and a compressed state. When a downward compression force is applied at contact surface 210, forward bending levers 208 and 207 urge the front portion of upper cantilevered spring member 201 to move forward and rotate downward, resulting in a downward and forward (to the left) displacement of contact surface 210. At the same time, the upper portion of upper cantilevered spring member 201 above nose 209, which includes backward bending lever 208, is rotated downward and backward (to the right), resulting in a downward and backward displacement of contact surface 210. As shown in FIG. 5c, the net horizontal displacement resulting from the forward and backward displacement of contact surface 210 is ‘d’, which is significantly less than ‘D’ shown in FIG. 4c.

Lower cantilevered spring member 203 undergoes a similar movement, except for the vertical movement is reversed. When an upward compression force is applied at contact surface 220, forward bending levers 214 and 215 urge the front portion of lower cantilevered spring member 203 to move forward and rotate upward, resulting in upward and forward displacement of contact surface 220. At the same time, the lower portion of lower cantilevered spring member 203 below nose 218, which includes backward bending lever 216, is rotated upward and backward, resulting in an upward and backward displacement of contact surface 210. As with upper cantilevered spring member 201, the net horizontal displacement of contact surface 220 will likewise be ‘d’ (not separately shown).

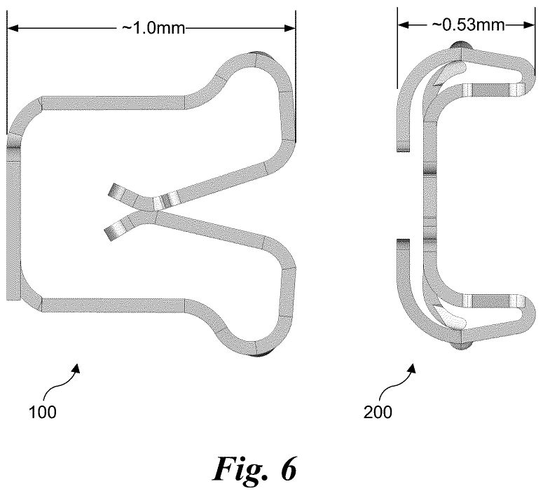

A comparison between the horizontal lengths of current CAMM connector pin 100 and proposed CAMM connector pin 200 in compressed states is shown in FIG. 6. In this example embodiment, the horizontal length of current CAMM connector pin 100 is approximately 1.0 mm, while the horizontal length of proposed CAMM connector pin 200 is approximately 0.53 mm, a reduction of nearly 50%.

One problem with the current design is the risk of off pad landing with the pin surface. This is primarily due to the natural arc the single lever takes during the compression process causing the pin to travel forward, as illustrated in FIG. 4C and discussed above. The proposed pin design utilizes a forward and backward traveling set of levers to mitigate this concern.

The opposing bend levers with shunting in the novel proposed design reduces the occupied space that the single lever on the existing CAMM connector pins do as well as reduces signal path between motherboard and (memory) module. This design allows for denser pin groups (more grounds to signal pins in some cases) while maintaining similar impedance and improving signaling. The opposing bend lever design with shunting also addresses concern over the pin contact landing on the edge of the pad, or off, due to the natural travel arc the pin takes during compression.

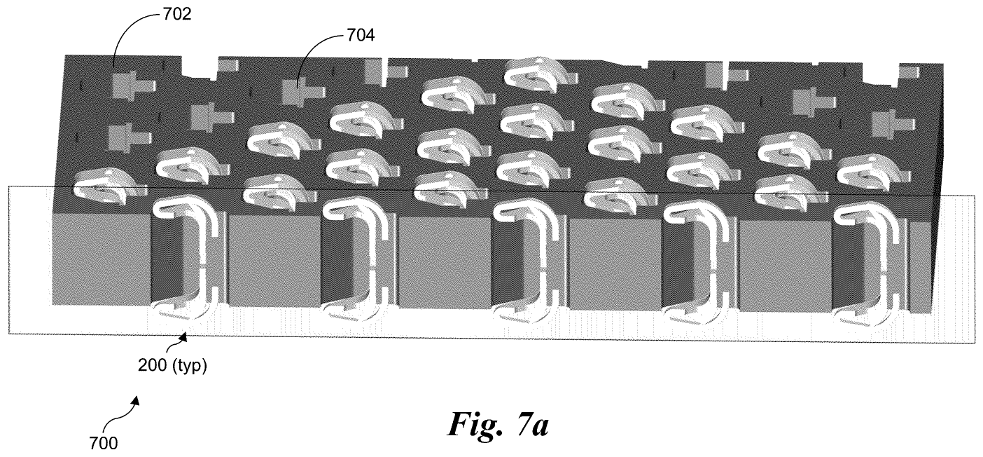

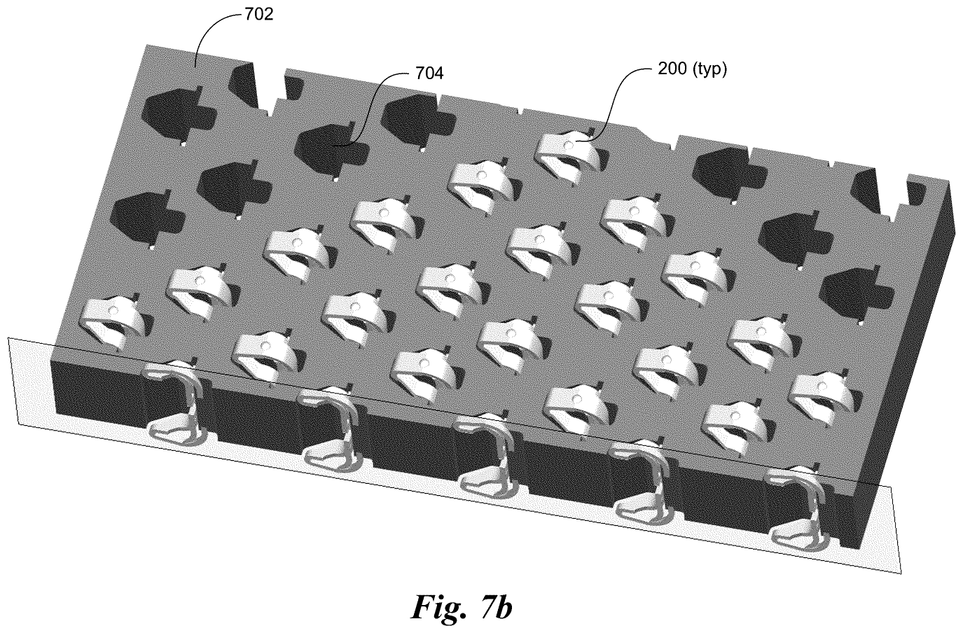

FIGS. 7a and 7b show cutaway views of a CAMM connector 700 including a body 702 having a plurality of connector pin housings 704 is which respective CAMM connector pins 200 are installed (noting there may be some connector pin housings 704 in which a CAMM connector pin is not installed, such as shown). FIG. 7c further shows a top cutaway view showing further details of the connector pin housings 704, which comprise a cavity including a slot 706 into which the body of the CAMM connector pin is inserted and held in place by means of a compression fit.

As shown in FIG. 7a, the connector pin housing has sufficient room for the CAMM connector pin to be compressed, with each of the upper and lower cantilevered spring members enabled to move freely without hitting any of the cavity walls. Meanwhile, the body of each CAMM connector pin is held in place and does not move relative to the body of CAMM connector 700.

FIG. 7c shows a first configuration of CAMM connector pins and connector pin housings. Generally, the CAMM connector pin configurations illustrated herein will comprise multiple rows of pins that are horizontally offset every other row, such as shown in FIG. 7c. In various embodiments the vertical pitch of the rows may be the same fixed value, or may slightly differ, as is the case shown in FIG. 7c, where ‘D2’ is slightly greater than ‘D1’ (˜13% in the illustrated embodiment).

The horizontal pitch of the columns may also be the same or differ. Moreover, within a given column the CAMM connector pins may be aligned or have a pattern of offsets. For example, the CAMM connector pins in column 708 are vertically aligned with no horizontal displacement. Conversely, the CAMM connector pins in column 710 have an alternating small horizontal displacement ‘H’ where the CAMM connector pins in every other row for the given column is horizontally offset from the CAMM connector pins in the rows above and below them.

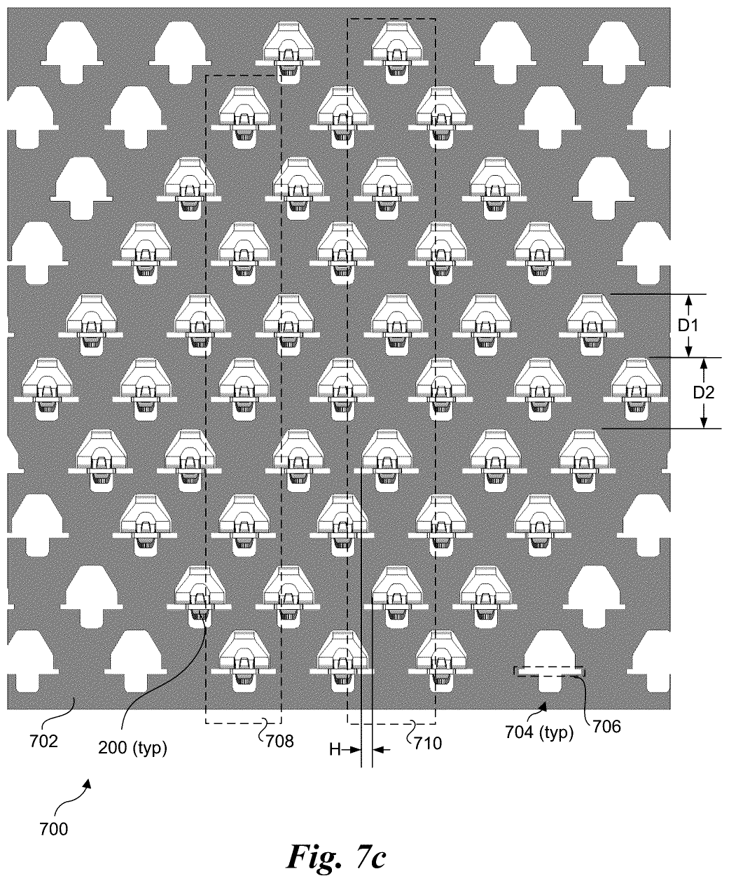

FIG. 8 shows an alternative configuration 800 of CAMM connector pins 200 where the vertical orientation of the CAMM connector pins in every other row is reversed. For example, the orientation of the CAMM connector pins in the first and third rows have their noses 209 pointing downward, while for the CAMM connector pins in the middle row have their noses 209 pointing upwards. Configuration 800 provides the advantage of reducing the vertical pitch between rows.

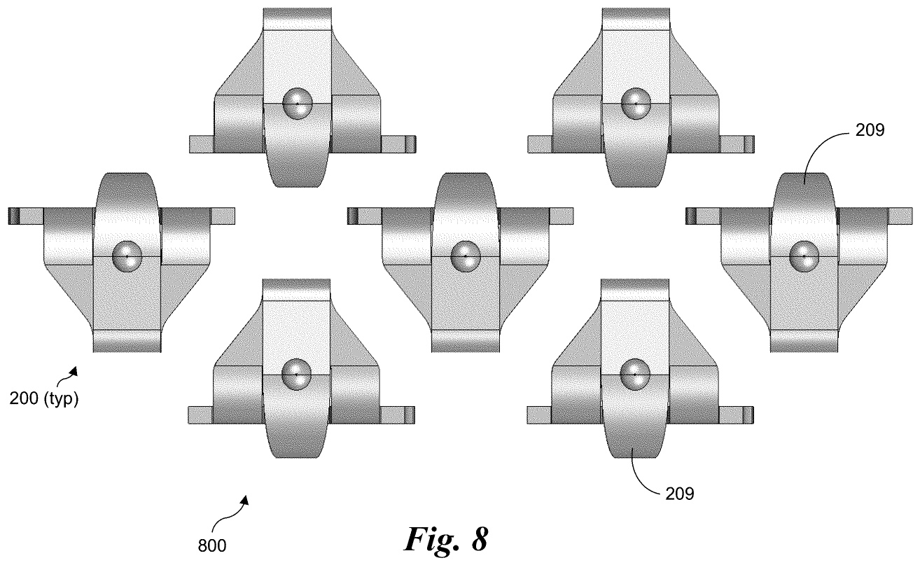

FIG. 9 shows a CAMM connector configuration 900 where CAMM connector pins are arranged in rows and columns with the CAMM connector pins rotated approximately 30 degrees counterclockwise. Of course, a similar configuration could be implemented with the CAMM connector pins rotated approximately 30 degrees clockwise. In the illustrated example the CAMM connector pins in the rows are arranged to be aligned horizontally while the CAMM connector pins in each column are aligned vertically. The use of 30 degrees rotation here is merely exemplary and non-limiting as substantially any angle could be used in a similar manner. For example, in some embodiments rotation may range from ±15-45 degrees relative to the horizontal axis for the rows.

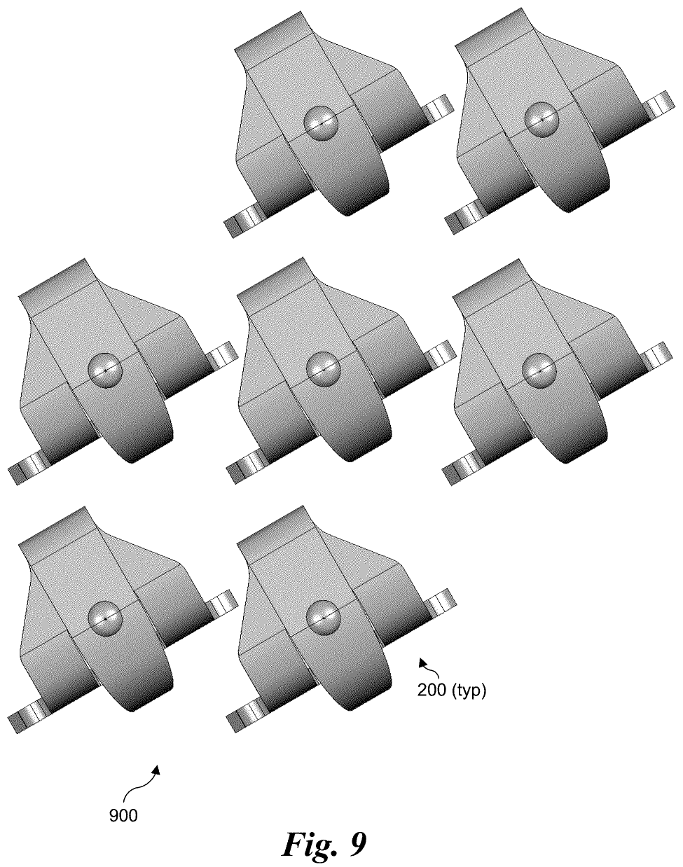

FIG. 10 shows a comparison of a CAMM connector pins configurations using the existing CAMM connector pins 100 and the proposed CAMM connector pins 200 when viewed from above, wherein both configurations 1000 and 1002 have the same number of pins with the same horizontal pitch.

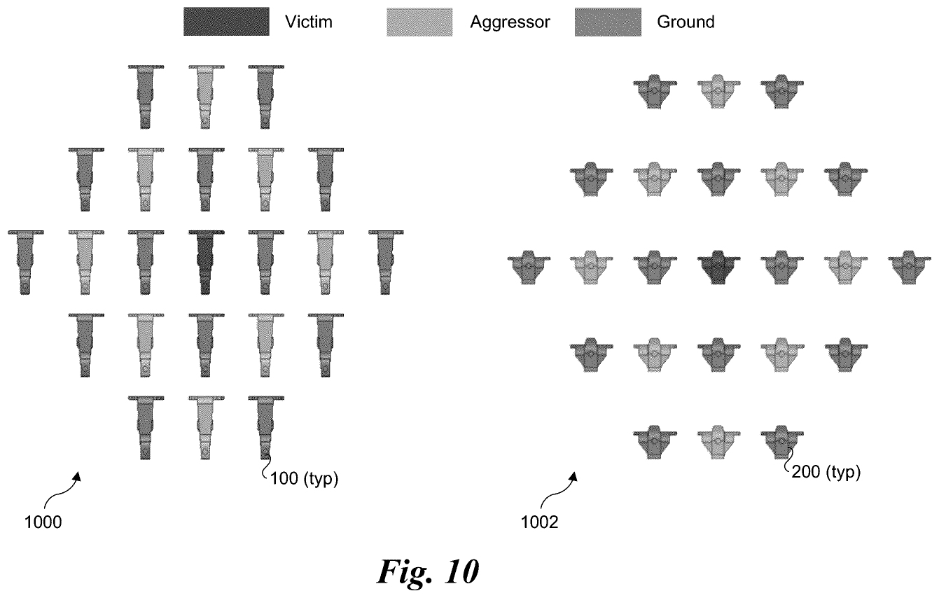

FIG. 11 shows a comparison between configuration 1000 using the existing CAMM connector pins 100 and a configuration 1100 of proposed CAMM connector pins 200 with extra rows of pins used for ground between rows including pins used for aggressors and the middle row including the victim. Since the size of CAMM connector pins 200 is less than CAMM connector pins 100, CAMM connector pins 200 can be arranged in patterns having reduced horizontal and vertical pitches (when compared to patterns using CAMM connector pins 100).

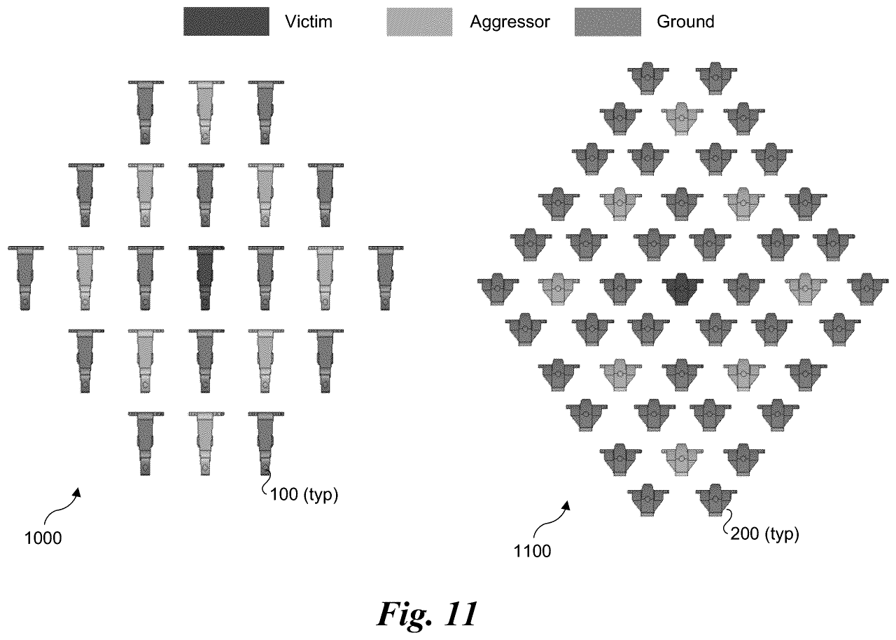

FIG. 12 shows a graph illustrating a far end cross talk (FEXT) power sum comparison between configurations 1000 (Current Pin), 1002 (New Pins), and 1100 (New Pins Extra Row of GND), with the FEXT power sum expressed in decibels (dB) over a frequency range from 0 through approximately 14.5 GHZ. The extra rows of ground pins significantly reduces the FEXT power sum across the frequency range.

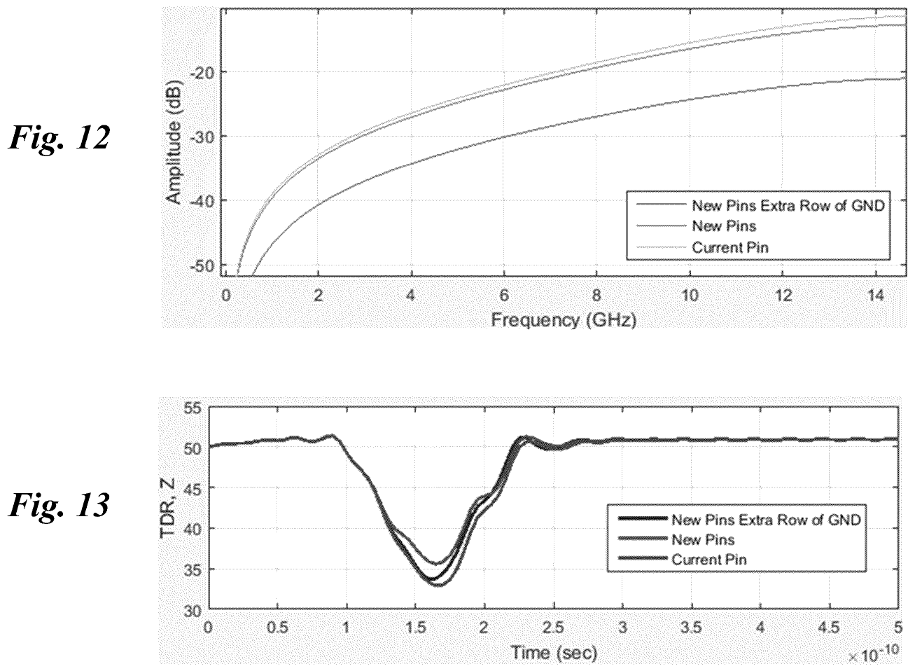

FIG. 13 shows a graph illustrating Time Domain Reflectometry (TDR) impedance vs. time using configurations 1000 (Current Pin), 1002 (New Pins), and 1100 (New Pins Extra Row of GND). The TDR impedances are similar across the pin designs and configurations.

Although some embodiments have been described in reference to particular implementations, other implementations are possible according to some embodiments. Additionally, the configuration and/or order of elements or other features illustrated in the drawings and/or described herein need not be arranged in the particular way illustrated and described. Many other configurations are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. A connector pin comprising:
a body;
an upper cantilevered spring member, coupled to an upper portion of the body; and
a lower cantilevered spring member, coupled to a lower portion of the body,
wherein each of the upper and lower cantilevered spring members include,
at least one forward bending lever; and
a backward bending lever.

2. The connector pin of claim 1, wherein the at least one forward bending lever comprises two forward bending levers.

3. The connector pin of claim 1, wherein each of the upper and lower cantilevered spring members folds back on itself to form a nose coupling the at least one forward bending lever to the backward bending lever.

4. The connector pin of claim 3, wherein the upper cantilevered spring member includes a tail that has an end portion extending downward, and wherein the lower cantilevered spring member includes a tail that has an end portion extending upward.

5. The connector pin of claim 1, further comprising:
an upper cantilevered shunting lever, coupled to the upper portion of the body;
a lower cantilevered shunting lever, coupled to the lower portion of the body;
a first landing surface, disposed on a top surface of the upper cantilevered spring member; and
a second landing surface, disposed on a bottom surface of the lower cantilevered spring member,
wherein when the connector pin is compressed, a free end of the upper cantilevered shunting lever is in contact with an inner surface of the upper cantilevered member below the first landing surface and a free end of the lower cantilevered shunting lever is in contact with an inner surface of the lower cantilevered member above the second landing surface.

6. The connector pin of claim 5, wherein when the pin is vertically compressed from an uncompressed state to a compressed state the at least one forward bending lever and the backward bending lever counteract one another to reduce a horizontal displacement of the first landing surface and second landing surface.

7. The connector pin of claim 5, wherein when the pin is compressed from an uncompressed state to a compressed state the first landing surface and second landing surface move in a vertical direction with a net horizontal displacement of approximately 0.3 millimeters.

8. The connector pin of claim 1, wherein the connector pin is a Compression Attached Memory Module (CAMM) connector pin configured to be installed in a CAMM connector housing.

9. The connector pin of claim 1, wherein the upper cantilevered spring member has first and second arms coupled to an upper portion of the body that merge to form a first unified spring member having a nose and looping backwards over the first and second arms and having an apex, and wherein the lower cantilevered spring member has first and second legs coupled to a lower portion of the body that merge to form a second unified spring member having a nose and looping backwards under the first and second legs and has bottom.

10. A connector, comprising:
a connector body, having a plurality of connector pins installed in respective connector pin housings, each connector pin comprising,
a body;
an upper cantilevered spring member, coupled to an upper portion of the body; and
a lower cantilevered spring member, coupled to a lower portion of the body,
wherein each of the upper and lower cantilevered spring members include,
at least one forward bending lever; and
a backward bending lever.

11. The connector of claim 10, wherein the upper cantilevered spring member has first and second arms coupled to an upper portion of the body that merge to form a first unified spring member having a nose and looping backwards over the first and second arms and having an apex, and wherein the lower cantilevered spring member has first and second legs coupled to a lower portion of the body that merge to form a second unified spring member having a nose and looping backwards under the first and second legs and has bottom.

12. The connector of claim 10, wherein the connector pins in alternating rows are flipped vertically relative to one another.

13. The connector of claim 10, wherein the connector pins are arranged in rows and columns and oriented at an angle ranging from ±15-45 degrees relative to a horizontal axis for the rows.

14. The connector of claim 10, wherein the connector pins are arranged in rows and columns, wherein the connector pins in adjacent columns are vertically displaced such that alternating rows are interposed and wherein connector pins in at least two of the columns have a horizontal displacement relative to other connector pins in those columns.

15. The connector of claim 10, wherein the connector pins are arranged in rows and columns and all connector pins in at least one row carry ground (GND) signals.

16. The connector of claim 10, wherein the connector comprises a Compression Attached Memory Module (CAMM) connector and the connector pins comprises CAMM connector pins.

17. A connector pin comprising:
a body;
an upper cantilevered spring member, having first and second arms coupled to an upper portion of the body, the first and second arms merging to form a first unified spring member having a nose and looping backwards over the first and second arms and having an apex; and
lower cantilevered spring member, having first and second legs coupled to a lower portion of the body, the first and second legs merging to form a second unified spring member having a nose and looping backwards under the first and second legs and having a bottom.

18. The connector pin of claim 17, further comprising:
an upper cantilevered shunting lever, coupled to the upper portion of the body; and
a lower cantilevered shunting lever, coupled to the lower portion of the body,
wherein when the connector pin is compressed, a free end of the upper cantilevered shunting lever is in contact with an inner surface of the upper cantilevered member below the apex and a free end of the lower cantilevered shunting lever is in contact with an inner surface of the lower cantilevered member above the bottom.

19. The connector pin of claim 18, further comprising:
a first landing surface, disposed on a top surface of the upper cantilevered spring member proximate to the apex of the upper unified section; and
a second landing surface, disposed on a bottom surface of the lower cantilevered spring member proximate to the bottom of the lower unified section.

20. The connector pin of claim 18, wherein each of the first and second arms comprise forward bending levers and the unified upper section comprises a backward bending lever, and wherein each of the first and second legs comprise forward bending levers and the unified lower section comprises a backward bending lever.
